(19) United States
(12) Patent Application Publication
(10) Pub. No.: US 2015/0075426 A1
(43) Pub. Date: Mar. 19, 2015

(54) PULSED LASER DEPOSITION SYSTEM

(71) Applicant: National Taiwan University, Taipei (TW)

(72) Inventors: CHING-FUH LIN, Taipei (TW); Yu-Wen CHENG, Taipei (TW); Hao-Yu WU, Taipei (TW)

(73) Assignee: National Taiwan University, Taipei (TW)

(21) Appl. No.: 14/158,004

(22) Filed: Jan. 17, 2014

(30) Foreign Application Priority Data
Sep. 13, 2013 (TW) 102133097

(51) Int. Cl. C23C 14/22; C23C 14/52

(52) U.S. Cl. CPC C23C 14/22; C23C 14/52
USPC 118/713; 118/715; 118/723 R; 118/725; 118/722

(57) ABSTRACT

The present invention relates to a pulsed laser deposition system, and particularly relates to a pulsed laser deposition system capable of using several different targets. In the pulsed laser deposition system, a beam-splitting device is provided to split a UV laser beam into several UV laser beams and to introduce these UV laser beams to different targets simultaneously. Therefore, the pulsed laser deposition system can use several different targets and can be used to form doped epitaxial layer (III-V semiconductor film) and ternary or quaternary epitaxial layer (III-V semiconductor film).

### CROSS REFERENCE

This application claims priority from Taiwan Patent Application No. 102133097, filed Sep. 13, 2013, the content of which are hereby incorporated by reference in their entirety for all purposes.

### BACKGROUND OF THE INVENTION

1. Field of the Invention

The present invention relates to a pulsed laser deposition system, and particularly relates to a pulsed laser deposition system capable of using several different targets.

2. Description of the Prior Art

Referring to FIG. 1, it illustrates a conventional pulsed laser deposition system 1 which is commonly used in pulsed laser deposition. The pulsed laser deposition system 1 uses an excimer laser including various visible light bands and UV bands as laser source 10. The pulsed laser deposition system 1 has a chamber 20, and there are a chamber door 22 for putting a substrate 29 and a target 27 into the chamber 20 and for taking the substrate 29 and the target 27 out the chamber 20, a single laser input window 24 for the excimer laser passing through, and a port 26 for connecting a vacuum pump 32 on the chamber 20. There are a target stage 28 for carrying or holding single target 27, and a carrier stage 30 for carrying or holding single substrate 29 inside the chamber 20. When pulsed laser deposition is performed by the pulsed laser deposition system 1, the excimer laser provided by the laser source 10 passes through the laser input window 24 to irradiate the target 27. The surface of the target absorbs the high energy of the excimer laser, and then, the surface of the target is gasified (or plasma-ized) by the high energy to form a clustered plasma gas having high kinetic energy. The clustered plasma gas having high kinetic energy is jetted to the substrate 29 to form a thin film (such as a III-V compound semiconductor film) on the substrate 29.

However, the conventional pulsed laser deposition system 1, can fabricate a III-V compound semiconductor film, but it can't fabricate a doped epitaxial layer or a ternary or more epitaxial layer. It is because the conventional pulsed laser deposition system 1 only can use one target once to perform pulsed laser deposition and the target is commonly composed of single material. Therefore, the conventional pulsed laser deposition system 1 can't fabricate a doped epitaxial layer or a ternary or more epitaxial layer. Although, in recent years, the target fabricated by mixing and pressure molding several different materials is developed for performing pulsed laser deposition to fabricate a doped epitaxial layer or a ternary or more epitaxial layer, but this method has following limitations and shortcomings. First, if an user wants to use the target composed of several different materials, the powders of the materials need to be pressed to form an ingot by a pressing machine. And then, the ingot composed of the several different materials is sintered to form a target composed of several different materials. However, not all kinds of materials can be pressed by the pressing machine or sintered. Once one of the materials (using to fabricate the target) can't be pressed by the pressing machine or sintered, the target can't be fabricated for performing pulsed laser deposition. Therefore, the epitaxial layer containing the material, which can't be pressed by the pressing machine or sintered, can't be formed by pulsed laser deposition, and the doped epitaxial layer or the ternary or more (such as quaternary) epitaxial layer containing the material, which can't be pressed by the pressing machine or sintered, can't be formed by pulsed laser deposition, either. Second, although the target can be fabricated by mixing, pressing and sintering several different materials with a certain ratio, but the materials are not distributed in the target uniformly. Therefore, in pulsed laser deposition process, the ratio of the compositions of plasma gas formed by the target can't be predicted and confirmed and it results in uncontrollable ratio of the compositions of the epitaxial layer fabricated by pulsed laser deposition with the target composed of several different materials. Third, it has a need of using a target composing a doped material for doping the epitaxial layer and an epitaxial material for forming the epitaxial layer, and the concentration of the doped material is much lower than the concentration of the epitaxial material. It means that the difference between the concentration of the doped material and the concentration of the epitaxial material is very large. However, the target composed of different materials, in which the difference between the concentration of the different materials is very large, can't be formed by current target fabricating technology. Therefore, the conventional pulsed laser deposition system (such as the pulsed laser deposition system 1 illustrated in FIG. 1) can't fabricate a doped epitaxial layer.

Besides, the area of the epitaxial layer fabricated by the conventional pulsed laser deposition system (such as the pulsed laser deposition system 1 illustrated in FIG. 1) is limited by the size of the conventional pulsed laser deposition system. Therefore, the conventional pulsed laser deposition system only can perform pulsed laser deposition to a substrate with small size (≦4 inches) but it can't perform pulsed laser deposition to a substrate with big size (>4 inches).

Therefore, it has a need of a pulsed laser deposition system capable of fabricating a doped epitaxial layer or a ternary or more (such as quaternary) epitaxial layer (or III-V compound semiconductor film). This pulsed laser deposition system also can control the doped concentration and the ratio of the compositions in the epitaxial layer efficiently and precisely, and it can perform pulsed laser deposition to a substrate with big size (>4 inches).

### SUMMARY OF THE INVENTION

In view of the foregoing, one object of the present invention is to provide a pulsed laser deposition system for overcoming above-mentioned shortcomings. This pulsed laser deposition system is capable of using one target or simultaneously using several different targets to perform pulsed laser deposition for fabricating a doped epitaxial layer or a ternary or more (such as quaternary) epitaxial layer (or III-V compound semiconductor film), and it can perform pulsed laser deposition to a substrate with big size (>4 inches).

According to one of the objects above, a pulsed laser deposition system is disclosed herein. The pulsed laser deposition system comprises a UV laser source, a chamber, a beam-splitting device, a target stage, and a carrier stage. The UV laser source and the beam-splitting device are deposed outside the chamber, and the target stage and the carrier stage are deposed inside the chamber. The UV laser source is capable of emitting an excimer laser including various UV bands for providing a UV laser to the pulsed laser deposition system. The beam-splitting device is used for splitting the UV laser provided by the UV laser source into a plurality of UV laser beams. The chamber has a plurality of laser input windows. The UV laser beams split by the beam-splitting device are respectively directed into different laser input windows at the same time by the beam-splitting device. And then, the UV laser beams respectively directed into different laser input windows are directed into the chamber through the laser input windows at the same time. The target stage is constructed of a plurality of target holding stages for carrying or holding one or more targets to perform pulsed laser deposition. The carrier stage is a carrier stage with big size (≧6 inches) and it is capable of carrying or holding substrates with big size (≧6 inches). The carrier stage is used for carrying or holding one or more substrates to perform pulsed laser deposition to the substrates. In the pulsed laser deposition system, the UV laser provided by the UV laser source is split into a plurality of UV laser beams through the beam-splitting device, and the UV laser beams enter into the chamber respectively through the laser input windows for respectively irradiating the different targets on the target stage. The different targets on the target stage are simultaneously gasified (or plasma-ized) by the UV laser beams to form a plasma (gas), and the plasma (gas) is jetted to the substrate(s) on the carrier stage for performing pulsed laser deposition to the substrate(s). Therefore, a doped epitaxial layer or a ternary or more (such as quaternary) epitaxial layer (or III-V compound semiconductor film) can be formed by this pulsed laser deposition system. The doped concentration and the ratio of the compositions in the epitaxial layer can be efficiently and precisely controlled by controlling the intensity of the UV laser beams which are directed into different laser input windows respectively.

Therefore, the present invention provides a pulsed laser deposition system. In the pulsed laser deposition system, by the beam-splitting device, a plurality of laser input windows deposed on the chamber, and the target stage constructed of a plurality of target holding stages, the UV laser provided by the UV laser source is split into a plurality of UV laser beams, and the UV laser beams simultaneously enter into the chamber and simultaneously irradiate on different targets respectively through different laser input windows. Therefore, the pulsed laser deposition system is capable of fabricating a doped epitaxial layer or a ternary or more (such as quaternary) epitaxial layer (or III-V compound semiconductor film). Furthermore, the pulsed laser deposition system is capable of perform pulsed laser deposition to a substrate with big size (>4 inches) because the carrier stage is a carrier stage with big size (≧6 inches).

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a drawing illustrating a conventional pulsed laser deposition system.

FIG. 2A to FIG. 2C are drawings respectively illustrating a pulsed laser deposition system in different view in accordance with one embodiment of the present invention.

FIG. 3A to FIG. 3B are drawings illustrating the target stage of the pulsed laser deposition system in accordance with one embodiment of the present invention.

FIG. 4A to FIG. 4C are drawings respectively illustrating different kinds of the carrier stage of the pulsed laser deposition system in accordance with another embodiment of the present invention.

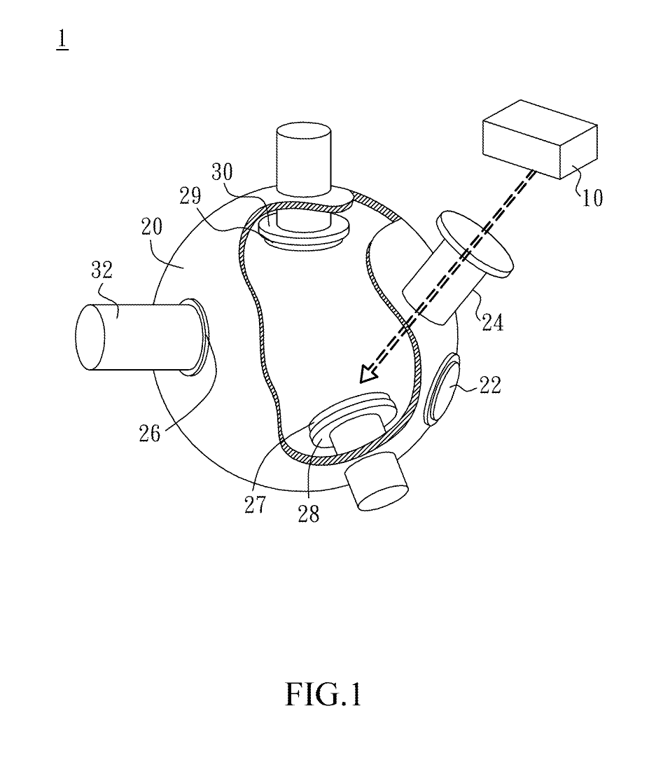

### DESCRIPTION OF THE PREFERRED EMBODIMENT

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components. Although specific embodiments have been illustrated and described, it will be appreciated by those skilled in the art that various modifications may be made without departing from the scope of the present invention, which is intended to be limited solely by the appended claims.

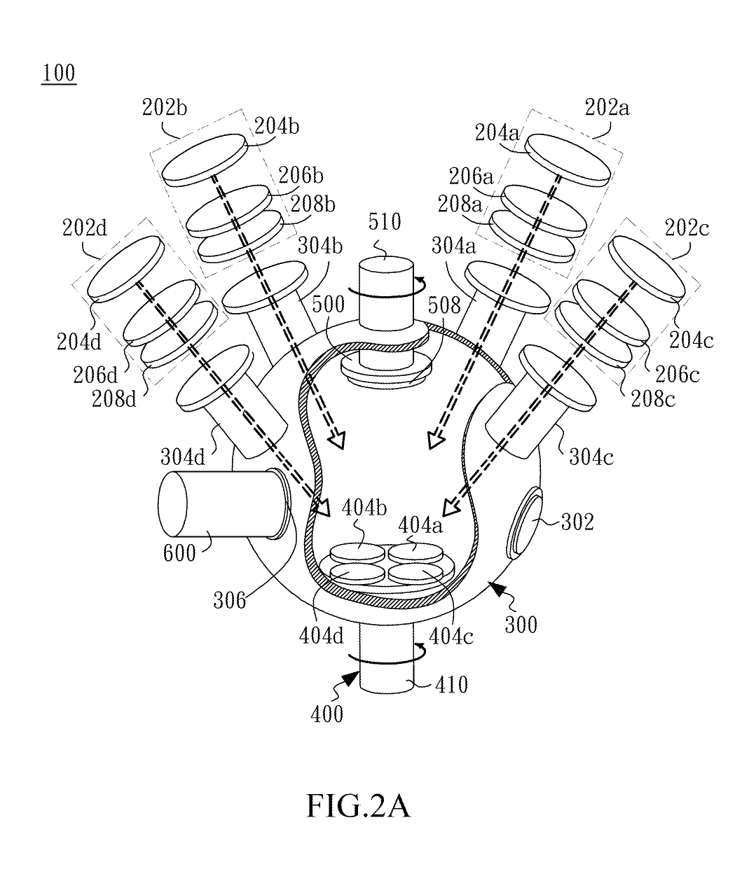

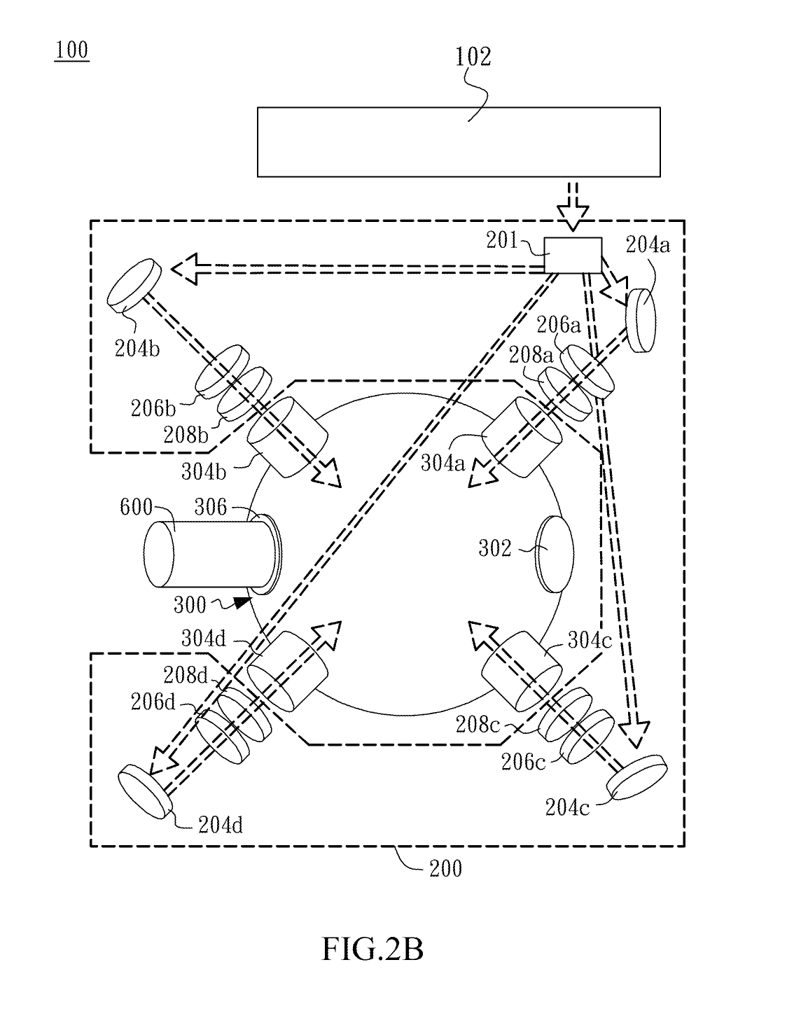

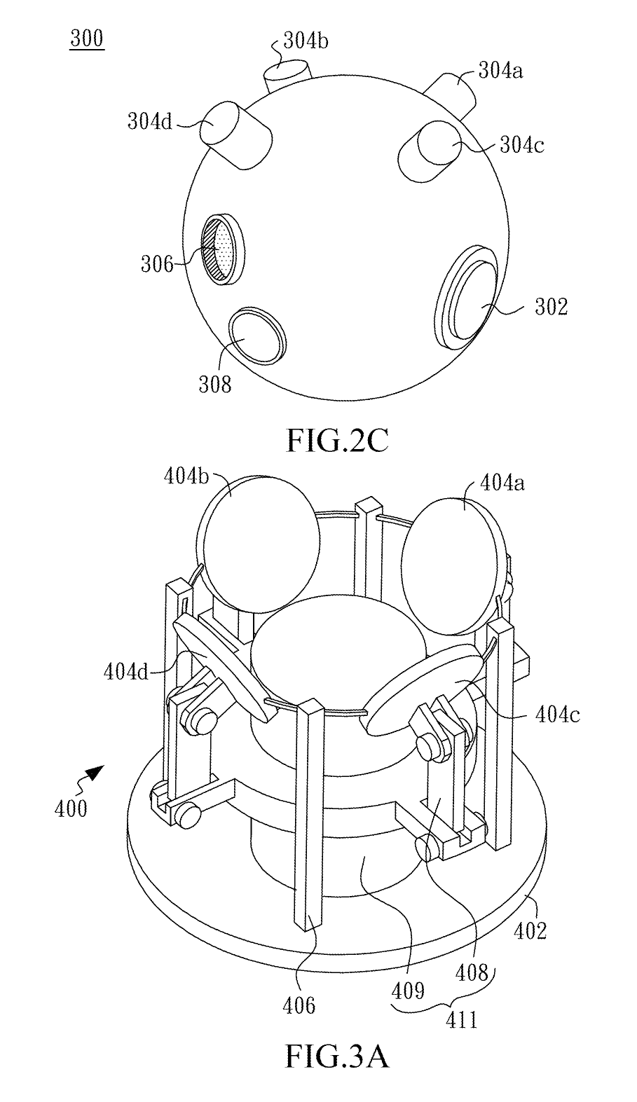

Referring to FIG. 2A, FIG. 2B, and FIG. 2C simultaneously, FIG. 2A is stereo drawing illustrating a pulsed laser deposition system 100 in accordance with one embodiment of the present invention, FIG. 2B is drawing in top view of the pulsed laser deposition system 100, and FIG. 2C is stereo drawing illustrating a chamber 300 of the pulsed laser deposition system 100. The pulsed laser deposition system 100 comprises a UV laser source 102, a chamber 300, a beam-splitting device 200, a target stage 400, and a carrier stage 500. The UV laser source 102 and the beam-splitting device 200 are deposed outside the chamber 300. The UV laser source 102 is a laser source capable of providing or emitting an excimer laser including various UV bands, and the UV laser source 102 is used to provide a UV laser to the pulsed laser deposition system 100 for performing pulsed laser deposition. The beam-splitting device 200 is used for splitting the UV laser provided by the UV laser source 102 into a plurality of UV laser beams and for directing these split UV laser beams into the chamber 300 to perform pulsed laser deposition. The chamber 300 provides a confined space for performing pulsed laser deposition. The target stage 400 deposed inside the chamber 300 for carrying or holding one or more targets to perform pulsed laser deposition. The carrier stage 500 deposed inside the chamber 300 for carrying or holding one or more substrates 508 to perform pulsed laser deposition to the substrates 508.

The chamber 300 comprises a chamber door 302, a plurality of laser input windows 304a, 304b, 304c, 304d, a vacuum pump port 306, and a view port 308. The target(s) and the substrate(s) 508 are put into the chamber 300 and taken out the chamber 300 through the chamber door 302. The laser input windows 304a, 304b, 304c, 304d are used to direct these split UV laser beams to enter the chamber 300, and these split UV laser beams enter the chamber 300 respectively through the laser input windows 304a, 304b, 304c, 304d. The view port 308 is a window made of a glass or other transparent materials. Therefore, the user can observe laser deposition condition in the chamber 300 through the view port 308. A vacuum pump 600 (for example a turbine pump or other vacuum pump) is connected with the chamber 300 by the vacuum pump port 306 for vacuuming the chamber 300 to control the pressure in the chamber 300. Therefore, the vacuum or pressure in the chamber 300 can achieve the required vacuum degree or pressure of pulsed laser deposition. Besides, in other embodiments of the present invention, there is a flange deposed one side of the chamber 300 for loading or equipping an additional device. The additional device may be a plasma gun or a RHEED gun, but it is not limit. Therefore, a plasma gun or a RHEED gun can directly configure on the pulsed laser deposition system 100 (or the chamber 300) of the present invention by the flange for observing the crystal of the epitaxial layer which is formed on the substrate by the laser deposition system of the present invention. Besides, according to requirements of pulsed laser deposition, other additional device also can configure on the pulsed laser deposition system (or the chamber) of the present invention by the flange. Although, in the pulsed laser deposition system 100 illustrated in FIG. 2A, FIG. 2B, and FIG. 2C, the chamber 300 comprises four laser input windows 304a, 304b, 304c, 304d, but it is not limit. In other embodiments of the present invention, according to requirements of pulsed laser deposition, the laser input windows can be increased, for example five, six, or more laser input windows, or the laser input windows can be decreased, for example two or three laser input windows.

The beam-splitting device 200 comprises a beam-splitting lens 201 and a plurality of directing lenses 202a, 202b, 202c, 202d. The beam-splitting lens 201 is used to split the UV laser emitted from the UV laser source 102 into several UV laser beams and to adjust the intensity of the UV laser beams. Each of the directing lenses 202a, 202b, 202c, 202d is corresponded to one of the laser input windows 304a, 304b, 304c, 304d for respectively directing the UV laser beams to different laser input windows 304a, 304b, 304c, 304d so the UV laser beams can simultaneously enter the chamber 300 respectively through different laser input windows 304a, 304b, 304c, 304d. In the present invention, each of the directing lenses must be corresponded to at least one of the laser input windows. Taking the pulsed laser deposition system 100 illustrated in FIG. 2A, FIG. 2B, and FIG. 2C for example, the directing lenses 202a is corresponded to the laser input window 304a for directing one of the UV laser beams to the laser input window 304a to enter the chamber 300 through the laser input window 304a, the directing lenses 202b is corresponded to the laser input window 304b for directing one of the UV laser beams to the laser input window 304b to enter the chamber 300 through the laser input window 304b, the directing lenses 202c is corresponded to the laser input window 304c for directing one of the UV laser beams to the laser input window 304c to enter the chamber 300 through the laser input window 304c, and the directing lenses 202d is corresponded to the laser input window 304d for directing one of the UV laser beams to the laser input window 304d to enter the chamber 300 through the laser input window 304d. Although, in the pulsed laser deposition system 100 illustrated in FIG. 2A, FIG. 2B, and FIG. 2C, the beam-splitting device 200 comprises four directing lenses 202a, 202b, 202c, 202d, but it is not limit. In other embodiments of the present invention, according to requirements of pulsed laser deposition, the directing lenses can be increased, for example five, six, or more directing lenses, or the directing lenses can be decreased, for example two or three directing lenses. Or, the directing lenses may be increased or decreased following change of the number of the laser input windows.

Each of the directing lenses 202a, 202b, 202c, 202d has a reflecting lens 204a, 204b, 204c, 204d and a focusing lens 206a, 206b, 206c, 206d. The reflecting lenses 204a, 204b, 204c, 204d are respectively deposed between the beam-splitting lens 201 and the laser input windows 304a, 304b, 304c, 304d, and each of the laser input windows 304a, 304b, 304c, 304d is corresponded to at least one of the reflecting lenses 204a, 204b, 204c, 204d. The laser input windows 304a is corresponded to the reflecting lens 204a, the laser input windows 304b is corresponded to the reflecting lens 204b, the laser input windows 304c is corresponded to the reflecting lens 204c, the laser input windows 304d is corresponded to the reflecting lens 204d. The reflecting lenses 204a, 204b, 204c, 204d are used to respectively reflect at least one of the UV laser beams and to direct the UV laser beam into the corresponded laser input window 304a, 304b, 304c, 304d. Each of the focusing lenses 206a, 206b, 206c, 206d is corresponded to one of the reflecting lenses 204a, 204b, 204c, 204d and one of the laser input window 304a, 304b, 304c, 304d, and each of the focusing lenses 206a, 206b, 206c, 206d is deposed between the corresponded reflecting lens 204a, 204b, 204c, 204d and the corresponded laser input window 304a, 304b, 304c, 304d. The focusing lens 206a is deposed between the reflecting lens 204a and the laser input window 304a and is corresponded to both of the reflecting lens 204a and the laser input window 304a. The focusing lens 206b is deposed between the reflecting lens 204b and the laser input window 304b and is corresponded to both of the reflecting lens 204b and the laser input window 304b. The focusing lens 206c is deposed between the reflecting lens 204c and the laser input window 304c and is corresponded to both of the reflecting lens 204c and the laser input window 304c. The focusing lens 206d is deposed between the reflecting lens 204d and the laser input window 304d and is corresponded to both of the reflecting lens 204d and the laser input window 304d. The focusing lenses 206a, 206b, 206c, 206d are used to focus the UV laser beams which are split by the beam-splitting lens 201 and respectively reflected by the reflecting lenses 204a, 204b, 204c, 204d for being desired to directed into the corresponded laser input windows 304a, 304b, 304c, 304d.

Besides, for controlling and adjusting intensity of the UV laser beams directed to the laser input windows 304a, 304b, 304c, 304d more efficiently, the beam-splitting device 200 maybe comprises one or more density filter lenses 208a, 208b, 208c, 208d for controlling and adjusting the intensity of the UV laser beams directed into the laser input windows 304a, 304b, 304c, 304d. Although, in the pulsed laser deposition system 100 illustrated in FIG. 2A, FIG. 2B, and FIG. 2C, each of the directing lenses 202a, 202b, 202c, 202d comprises a density filter lens 208a, 208b, 208c, 208d, and each of the directing lenses 202a, 202b, 202c, 202d is deposed between one of the focusing lenses 206a, 206b, 206c, 206d and one of the laser input windows 304a, 304b, 304c, 304d for being corresponded to the focusing lens and the laser input window, but it is not limit. In other embodiments of the present invention, people can determine whether it is necessary to add a density filter lens into each of the directing lenses, which directing lenses has need of adding a density filter lens into, or how much density filter lens need to be added into each of the directing lenses for making the intensity of different UV laser beams directed into different laser input windows to have different intensity or respectively have certain intensity, according to the desired intensity of the UV laser beam directed to each of the directing lens or each of the laser input window or according to desired intensity of the UV laser beam for different targets. Although, in the pulsed laser deposition system 100 illustrated in FIG. 2A, FIG. 2B, and FIG. 2C, each of the density filter lenses 208a, 208b, 208c, 208d is deposed between one of the focusing lenses 206a, 206b, 206c, 206d and one of the laser input windows 304a, 304b, 304c, 304d, but it is not limit. In other embodiments of the present invention, the density filter lenses 208a, 208b, 208c, 208d can be deposed between the beam-splitting lens 201 and the reflecting lenses 204a, 204b, 204c, 204d, between the reflecting lenses 204a, 204b, 204c, 204d and the focusing lenses 206a, 206b, 206c, 206d, or between the focusing lenses 206a, 206b, 206c, 206d and the laser input windows 304a, 304b, 304c, 304d according to requirements. Furthermore, other embodiments of the present invention, baffles maybe adopted instead of the density filter lenses for controlling and adjusting the intensity of the UV laser beams directed into the laser input windows. The baffles can be deposed between the beam-splitting lens and the reflecting lenses, between the reflecting lenses and the focusing lenses, or between the focusing lenses and the laser input windows according to requirements.

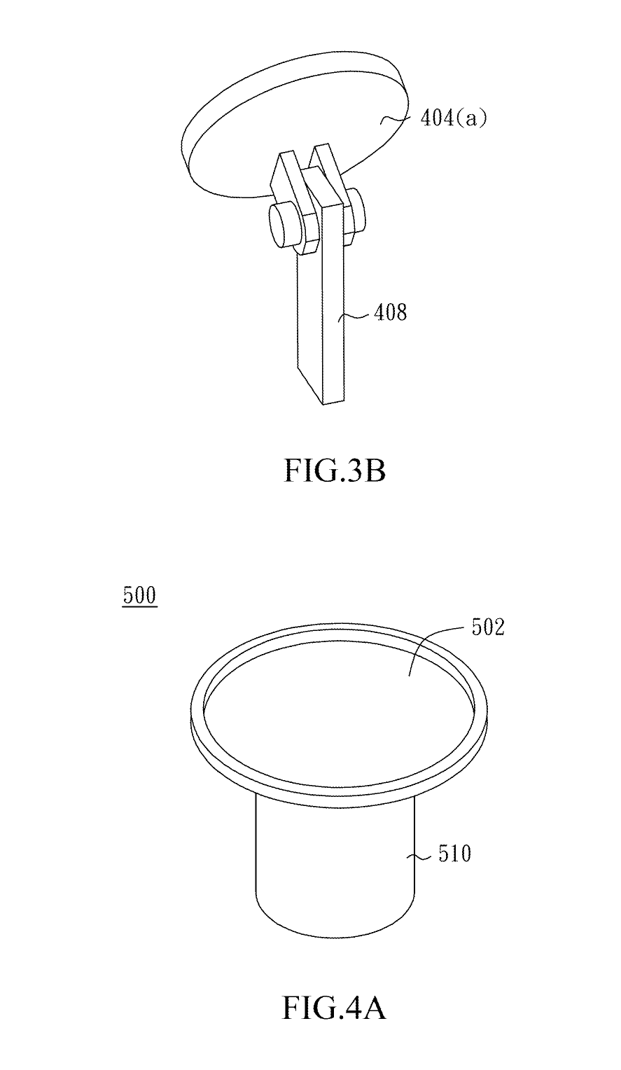

Referring to FIG. 2A, FIG. 2B, FIG. 2C, FIG. 3A, and FIG. 3B simultaneously, the target stage 400 comprises a base 402, a plurality of pillars 406 deposed on the base 402, a plurality of target holding stages 404a, 404b, 404c, 404d, and a target inclination controlling device 411. Each of the target holding stages 404a, 404b, 404c, 404d is deposed between two adjacent pillars 406 and Each of the target holding stages 404a, 404b, 404c, 404d is pinjointed to the two adjacent pillars 406. Therefore, each of the target holding stages 404a, 404b, 404c, 404d is indirectly deposed on the base 402 through the pillars 406 and each of the target holding stages 404a, 404b, 404c, 404d is able to rotate between the two adjacent pillars 406. The target holding stages 404a, 404b, 404c, 404d are used for holding or carrying targets thereon to perform pulsed laser deposition. The target inclination controlling device 411 is used for controlling and adjusting inclination angles of the target holding stages 404a, 404b, 404c, 404d to make the targets held on the target holding stages 404a, 404b, 404c, 404d to be scanned back and forth by the UV laser beams with different inclination angles.

The target inclination controlling device 411 comprises an inclination angle controlling column 409 and a plurality of inclination angle spindles 408. The inclination angle controlling column 409 is deposed on the base 402 and it is able to move up and down (or rise and descend) on the base 402. The inclination angle spindles 408 are connections between the inclination angle controlling column 409 and the target holding stages 404a, 404b, 404c, 404d. Each of the target holding stages 404a, 404b, 404c, 404d is corresponded to one of the inclination angle spindles 408. One end of each of the inclination angle spindles 408 is hinge connected to one of the target holding stages 404a, 404b, 404c, 404d (or the corresponded target holding stages) for driving the target holding stage 404a, 404b, 404c, 404d to rotate up and down. Therefore, each of the target holding stages 404a, 404b, 404c, 404d can be inclined with a predetermined angle by the corresponded inclination angle spindle 408. Another end of each of the inclination angle spindles 408 is hinge connected to the inclination angle controlling column 409 so that each of the inclination angle spindles 408 is able to move up and down following moving (or rising and descending) of the inclination angle controlling column 409 for driving corresponded target holding stage 404a, 404b, 404c, 404d to rotate upward or downward. Therefore, the inclination angle of the corresponded target holding stage 404a, 404b, 404c, 404d can be controlled by this way. When the inclination angle controlling column 409 moves up (or rises), the inclination angle controlling column 409 drives the inclination angle spindles 408 to move down (or descend). And then, following the downwardly moving (or descend) of the inclination angle spindles 408, the inclination angle spindles 408 drive the target holding stages 404a, 404b, 404c, 404d to rotate downward so that the target holding stages 404a, 404b, 404c, 404d are inclined downward at a certain or predetermined angle (as showed in FIG. 3A). When the inclination angle controlling column 409 moves down (or descends), the inclination angle controlling column 409 drives the inclination angle spindles 408 to move up (or rise). And then, following the upwardly moving (or rising) of the inclination angle spindles 408, the inclination angle spindles 408 drive the target holding stages 404a, 404b, 404c, 404d to rotate upward so that the target holding stages 404a, 404b, 404c, 404d are inclined upward at a certain or predetermined angle or the target holding stages 404a, 404b, 404c, 404d come back to the horizontal positions. The upwardly moving (or rising) distances and the downwardly moving (or descending) distances of the inclination angle spindles 408 can be controlled and adjusted respectively by controlling and adjusting the downwardly moving (or descending) distance and the upwardly moving (or rising) distance of the inclination angle controlling column 409. Further, the downwardly rotation angles (or the downwardly inclination angles) and the upwardly rotation angles (or the upwardly inclination angles) of the target holding stages 404a, 404b, 404c, 404d can be controlled and adjusted respectively by controlling and adjusting the upwardly moving (or rising) distance and downwardly moving (or descending) distance of the inclination angle controlling column 409. The downwardly rotation angles of the target holding stages 404a, 404b, 404c, 404d means the downwardly inclination angles of the target holding stages 404a, 404b, 404c, 404d, and the upwardly rotation angles of the target holding stages 404a, 404b, 404c, 404d means the upwardly inclination angles of the target holding stages 404a, 404b, 404c, 404d. Therefore, the pulsed laser deposition system 100 of the present invention can control the targets to perform pulsed laser deposition with different inclination angles by the target inclination controlling device 411.

Besides, there is a rotating device 410 deposed under the target stage 400 for rotating the target stage 400 and thereby the target holding stages 404a, 404b, 404c, 404d are able to be revolved or rotated back and forth around center of the target stage 400. By this revolving or rotating, the target holding stage 404a, 404b, 404c, 404d corresponded to each of the laser input windows 304a, 304b, 304c, 304d can be changed from one to another. Therefore, the pulsed laser deposition system 100 can change targets of laser deposition form one to another during laser deposition by the rotating device 410. Furthermore, the rotating device 410 can rotate the target stage 400 and thereby the targets put in the target holding stages 404a, 404b, 404c, 404d are able to be horizontally scanned back and forth by the UV laser beams. Therefore, the pulsed laser deposition system 100 of the present invention can control the targets put in the target holding stages 404a, 404b, 404c, 404d to be scanned back and forth with different inclination angles by the target inclination controlling device 411 and the rotating device 410. Although, the target stage 400 illustrated in FIG. 2A and FIG. 3A has four target holding stages 404a, 404b, 404c, 404d, but it is not limit. In other embodiments of the present invention, the target holding stages 404a, 404b, 404c, 404d can be increased or decreased according to requirements, but the number of the target holding stages must be much than the number of the laser input windows or equal to the number of the laser input windows. Preferably, the number of the target holding stages is a multiple of the number of the laser input windows because it is useful and convenient for changing the targets during pulsed laser deposition. Therefore, the pulsed laser deposition system 100 of the present invention can change different targets to perform pulsed laser deposition during pulsed laser deposition for forming a epitaxial layer (or III-V compound semiconductor film) which is more than ternary.

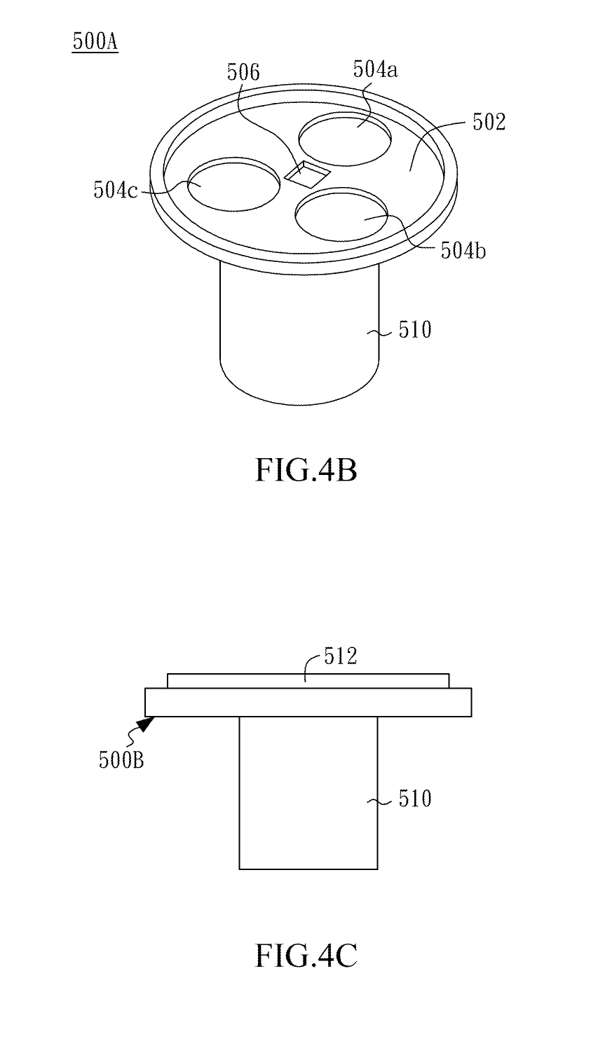

Referring to FIG. 2A and FIG. 4A simultaneously, the carrier stage 500 is a carrier stage with big size (≧6 inches). The size of the carrier stage 500 is 6 inches to 12 inches but it is not limit. In some embodiments of the present invention, the size of the carrier stage 500 maybe bigger than 12 inches. The carrier stage 500 comprises a cavity 502 capable of putting or holding a substrate having a size of 6 inches to 12 inches thereon (as showed in FIG. 4A). Therefore, the pulsed laser deposition system 100 of the present invention can perform pulsed laser deposition to the substrates with big size (6 inches-12 inches) by the carrier stage 500. Referring to FIG. 4B, it is a drawing illustrating another kind of the carrier stage 500A of the pulsed laser deposition system in accordance with another embodiment of the present invention. The carrier stage 500A comprises a cavity 502 capable of putting or holding a substrate having a size of 6 inches to 12 inches thereon and several small substrate containing pits 504a, 504b, 504c, 506 deposed in the cavity 502 for putting or holding one or more substrates having small size (<6 inches) thereon to perform laser deposition. The small substrate containing pits 504a, 504b, 504c is used for putting or holding substrates having size of 2 inches to 4 inches thereon to perform laser deposition. The small substrate containing pits 506 is used for putting or holding substrates having smaller size than of 2 inches thereon to perform laser deposition. Therefore, by the carrier stage 500A, the pulsed laser deposition system 100 of the present invention can perform pulsed laser deposition to the substrates with big size (>6 inches), and also can perform pulsed laser deposition to the substrates with small size (<6 inches). Further, the pulsed laser deposition system 100 of the present invention can simultaneously perform pulsed laser deposition to the substrates with different small sizes. Although the carrier stage 500A illustrated in FIG. 4B has three small substrate containing pits 504a, 504b, 504c (for substrates having size of 2 inches to 4 inches) and one small substrate containing pits 506 (for substrates having smaller than 2 inches), but it is not limit. In other embodiments of the present invention, the size and the number of the small substrate containing pits can be changed according to requirements.

Referring to FIG. 4C, it is a drawing illustrating still another kind of the carrier stage 500B of the pulsed laser deposition system in accordance with still another embodiment of the present invention. There is no cavity, which is capable of putting or holding a substrate thereon, on the carrier stage 500B. On the contrary, there is a carrier 512, which is capable of putting or holding a substrate thereon, deposed on the carrier stage 500B. The carrier 512 may comprise a cavity capable of putting or holding a substrate having a size of 6 inches to 12 inches thereon as showed in FIG. 4A. Or, the carrier 512 may comprise a cavity capable of putting or holding a substrate having a size of 6 inches to 12 inches thereon and several small substrate containing pits deposed in the cavity for putting or holding one or more substrates having small size (<6 inches) thereon as showed in FIG. 4B. The carrier 512 may be a carrier fixed on the carrier stage or a movable carrier which can be taken from the carrier stage for changing the carrier with different sizes and designs.

Besides, referring FIG. 2A, the carrier stage 500 comprises a rotation-and-rise controlling device 510 for controlling the carrier stage 500 to rotate in order to perform laser deposition to all of the substrates 508 put on the carrier stage 500 uniformly and for rising and descending the carrier stage 500 to control the work distance between the carrier stage 500 and the target stage 400. The rotation-and-rise controlling device 510 may control the carrier stage 500 to rise and descend by a manual way (for example manually rotating a turntable by hands) or a mechanical way (for example using a lifting mechanism). Therefore, the work distance between the carrier stage 500 and the target stage 400 can be adjusted within a range of 10 centimeter (cm) to 40 centimeter (cm) by the rotation-and-rise controlling device 510 according to requirements. In the pulsed laser deposition system of the present invention, a heating device equipped above, beside, or around the carrier stage for heating the substrate put on the carrier stage to perform laser deposition.

Although, the pulsed laser deposition system 100 illustrated in FIG. 2B has only one beam-splitting lens 201, but in the other embodiments of the present invention, one or more beam-splitting lenses can be added into the pulsed laser deposition system according to the desired number of the UV laser beams. Therefore, the UV laser provided by laser source can be split into more UV laser beams by additional beam-splitting lens(es) and a epitaxial layer (or III-V compound semiconductor film) which is more than ternary or has more dopants can be formed by the pulsed laser deposition system having a plurality of the beam-splitting lenses.

Referring FIG. 2A, FIG. 2B, and FIG. 2C simultaneously, the process and operation of pulsed laser deposition by using the pulsed laser deposition system is detailed as following: After the laser source 102 emits a UV laser, the beam-splitting lens 201 in the beam-splitting device 200 splits the UV laser into several UV laser beams. After the UV laser is split into several UV laser beams, the directing lenses 202a, 202b, 202c, 202d in the beam-splitting device 200 direct several UV laser beams to corresponded laser input windows 304a, 304b, 304c, 304d wherein each of laser input windows 304a, 304b, 304c, 304d is corresponded to one of the directing lenses 202a, 202b, 202c, 202d and each of the laser input windows 304a, 304b, 304c, 304d has one of the UV laser beams directed thereto by the corresponded directing lenses 202a, 202b, 202c, 202d. Before the UV laser beams enter the chamber 300 through the laser input windows 304a, 304b, 304c, 304d, the intensity of the of the UV laser beams are adjusted by the beam-splitting lens 201 and the density filter lenses 208a, 208b, 208c, 208d (or baffles). After the UV laser beams are directed to corresponded laser input windows 304a, 304b, 304c, 304d, the UV laser beams enter the chamber 300 respectively through the laser input windows 304a, 304b, 304c, 304d, and then the UV laser beams passed through different laser input windows 304a, 304b, 304c, 304d simultaneously irradiate on the targets put on different the target holding stages 404a, 404b, 404c, 404d for gasifying (or plasma-izing) the targets to perform the pulsed laser deposition wherein the target holding stages 404a, 404b, 404c, 404d are corresponded to different laser input windows 304a, 304b, 304c, 304d. When the UV laser beams irradiate on the targets, the inclination angles of the target holding stages 404a, 404b, 404c, 404d and the target put on the target holding stages 404a, 404b, 404c, 404d are controlled and adjusted by the target inclination controlling device 411, and the rotating device 410 controls the target holding stages 404a, 404b, 404c, 404d and the target put on the target holding stages 404a, 404b, 404c, 404d to horizontally rotate back and forth. Therefore, the UV laser beams irradiating on the targets can scan the targets back and forth with different (inclination) angles according requirements. During the pulsed laser deposition, each of the laser input windows 304a, 304b, 304c, 304d can be changed to be corresponded to different target holding stages by the rotating device 410. It means that each of the UV laser beams can be changed to irradiate on different the target holding stages and targets by the rotating device 410 for forming a epitaxial layer (or III-V compound semiconductor film) which is more than ternary or quaternary. Besides, a substrate with big size or several substrates with small size can be put on the carrier stage 500 for being performed pulsed laser deposition thereon. During the pulsed laser deposition, the rotation-and-rise controlling device 510 controls the carrier stage 500 and the substrate(s) put on the carrier stage 500 to rotate for uniformly performing pulsed laser deposition on the substrate(s), and the work distance between carrier stage 500 and the target stage is controlled and adjusted by the rotation-and-rise controlling device 510. Therefore, the pulsed laser deposition system 100 of the present invention can simultaneously gasify (or plasma-ize) several targets to perform pulsed laser deposition. Furthermore, in the pulsed laser deposition system 100 of the present invention, the ratio of the compositions of a epitaxial layer (or III-V compound semiconductor film) or the doped concentration of the a epitaxial layer (or III-V compound semiconductor film) can be precisely controlled by adjusting the intensity of the UV laser beams and controlling the sizes of the targets.

Referring FIG. 2A, FIG. 2B, and FIG. 2C simultaneously, the process and operation of forming a ternary or more (such as quaternary) epitaxial layer (or III-V compound semiconductor film) by using the pulsed laser deposition system is detailed as following: First, the laser source 102 is turned on to emit a UV laser. After, the beam-splitting lens 201 in the beam-splitting device 200 splits the UV laser into several UV laser beams, and then, the beam-splitting lens 201 adjusts the intensity of the UV laser beams. After, the reflecting lenses 204a, 204b, 204c, 204d reflect the UV laser beams to the corresponded laser input windows 304a, 304b, 304c, 304d respectively. And then, the UV laser beams are respectively focused at the corresponded laser input windows 304a, 304b, 304c, 304d by the focusing lenses 206a, 206b, 206c, 206d before the UV laser beams enter the chamber 300 through the laser input windows 304a, 304b, 304c, 304d. After the UV laser beams are focused, intensity of each of the UV laser beams is precisely adjusted by the density filter lenses 208a, 208b, 208c, 208d (or baffles) according to the energy for gasifying (or plasma-izing) the target put on the target holding stage 404a, 404b, 404c, 404d corresponded to the laser input window 304a, 304b, 304c, 304d which the UV laser beam passes through. After, the UV laser beams simultaneously enter the chamber through different laser input windows 304a, 304b, 304c, 304d, and then, the UV laser beams respectively irradiate on different target holding stages 404a, 404b, 404c, 404d on the target stage 400. Next, a substrate or substrates are put on the carrier stage 500 and the different targets are put one different target holding stages 404a, 404b, 404c, 404d. After, the chamber door 302 is closed and the vacuum pump 600 is turned on to vacuum the chamber 300 for achieving the required vacuum degree or pressure of pulsed laser deposition. And then, the chamber 300 is heated to the required temperature and the reaction gases are introduced into the chamber 300. Next, the UV laser beams simultaneously enter the chamber through different laser input windows 304a, 304b, 304c, 304d and simultaneously irradiate on different targets put on different target holding stages 404a, 404b, 404c, 404d for gasifying (or plasma-izing) the targets to perform the pulsed laser deposition wherein the target holding stages 404a, 404b, 404c, 404d are corresponded to different laser input windows 304a, 304b, 304c, 304d. By splitting a UV laser into several UV laser beams and precisely controlling and adjusting intensity of the UV laser beams, several targets can be simultaneously gasified (or plasma-ized). Therefore, the ratio of the compositions of a ternary or more (such as quaternary) epitaxial layer (or III-V compound semiconductor film) can be precisely controlled.

Referring FIG. 2A, FIG. 2B, and FIG. 2C simultaneously, the process and operation of forming a doped epitaxial layer (or III-V compound semiconductor film) by using the pulsed laser deposition system is detailed as following: First, the laser source 102 is turned on to emit a UV laser. After the laser source 102 emits a UV laser, the beam-splitting lens 201 splits the UV laser into several UV laser beams, and then, the beam-splitting lens 201 adjusts the intensity of the UV laser beams. After, the reflecting lenses 204a, 204b, 204c, 204d reflect the UV laser beams to the corresponded laser input windows 304a, 304b, 304c, 304d respectively. And then, the UV laser beams are respectively focused at the corresponded laser input windows 304a, 304b, 304c, 304d by the focusing lenses 206a, 206b, 206c, 206d before the UV laser beams enter the chamber 300 through the laser input windows 304a, 304b, 304c, 304d. After the UV laser beams are focused, intensity of each of the UV laser beams is precisely adjusted by the density filter lenses 208a, 208b, 208c, 208d (or baffles) according to the energy for gasifying (or plasma-izing) the target put on the target holding stage 404a, 404b, 404c, 404d corresponded to the laser input window 304a, 304b, 304c, 304d which the UV laser beam passes through. The energy of the UV laser beam(s) used to gasify (or plasma-ize) the doping target(s), which is used to dope the epitaxial layer, is much weaker than the energy of the UV laser beam(s) used to gasify (or plasma-ize) the other target(s) which is used to form the epitaxial layer. Therefore, more additional density filter lenses or one or more additional baffles can be added for further weakening the energy of the UV laser beam(s) used to gasify (or plasma-ize) the doping target(s). After, the UV laser beams simultaneously enter the chamber through different laser input windows 304a, 304b, 304c, 304d, and then, the UV laser beams respectively irradiate on different target holding stages 404a, 404b, 404c, 404d. It is noticed that the weakened UV laser beam(s) must irradiate on the target holding stage(s) which is used to hold or carry the doping target. Next, a substrate or substrates are put on the carrier stage 500 and the different targets are put one different target holding stages 404a, 404b, 404c, 404d. It is noticed that the doping target must be put on the target holding stage(s) which will be irradiated by the weakened UV laser beam(s) and is corresponded to the laser input window for the weakened UV laser beam pass through. After, the chamber door 302 is closed and the vacuum pump 600 is turned on to vacuum the chamber 300 for achieving the required vacuum degree or pressure of pulsed laser deposition. And then, the chamber 300 is heated to the required temperature and the reaction gases are introduced into the chamber 300. Next, the UV laser beams simultaneously enter the chamber through different laser input windows 304a, 304b, 304c, 304d and simultaneously irradiate on different targets put on different target holding stages 404a, 404b, 404c, 404d for gasifying (or plasma-izing) the targets to perform the pulsed laser deposition wherein the target holding stages 404a, 404b, 404c, 404d are corresponded to different laser input windows 304a, 304b, 304c, 304d. By splitting a UV laser into several UV laser beams, which have much difference between their intensity, and by precisely controlling and adjusting intensity of the UV laser beams, several targets (including the doping targets and the targets for forming the epitaxial layer) can be simultaneously gasified (or plasma-ized). Therefore, the ratio of the compositions of a doped epitaxial layer (or III-V compound semiconductor film) and the doping concentration of a doped epitaxial layer (or III-V compound semiconductor film) can be precisely controlled.

According to foregoing embodiments, the present invention provides a pulsed laser deposition system. In the pulsed laser deposition system, by the beam-splitting device, a plurality of laser input windows deposed on the chamber, and the target stage constructed of a plurality of target holding stages, the UV laser provided by the UI laser source is split into a plurality of UV laser beams, and the UV laser beams simultaneously enter into the chamber and simultaneously irradiate on different targets respectively through different laser input windows. Therefore, the pulsed laser deposition system is capable of fabricating a doped epitaxial layer or a ternary or more (such as quaternary) epitaxial layer (or III-V compound semiconductor film). Furthermore, the pulsed laser deposition system is capable of perform pulsed laser deposition to a substrate with big size (>4 inches) because the carrier stage is a carrier stage with big size (≧6 inches).

What is claimed is:

1. A pulsed laser deposition system, comprising:
a UV laser source for providing a UV laser to perform deposition;
a chamber wherein the chamber has a plurality of laser input windows;
a beam-splitting device for splitting the UV laser provided by the UV laser source into a plurality of UV laser beams and for respectively directing the plurality of UV laser beams into the chamber through the plurality of laser input windows;
a target stage for carrying or holding one or more targets to perform pulsed laser deposition and
a carrier stage for carrying or holding one or more substrates to perform pulsed laser deposition to the substrates.

2. The pulsed laser deposition system of claim 1, wherein the chamber comprises a chamber door for putting the desired substrates and the desired targets into the chamber and for taking the desired substrates and the desired targets out the chamber.

3. The pulsed laser deposition system of claim 1, wherein the chamber comprises a vacuum pump port for connecting a vacuum pump to vacuum the chamber and to control the pressure in the chamber.

4. The pulsed laser deposition system of claim 1, wherein the chamber comprises a view port for observing laser deposition condition in the chamber.

5. The pulsed laser deposition system of claim 1, the chamber comprises a flange deposed one side of the chamber for loading or equipping an additional device.

6. The pulsed laser deposition system of claim 5, wherein the additional device is a plasma gun or a RHEED gun.

7. The pulsed laser deposition system of claim 1, wherein the beam-splitting device comprises:
a beam-splitting lens for splitting the UV laser provided by the UV laser source into a plurality of UV laser beams; and
a plurality of directing lenses for respectively directing the plurality of UV laser beams to the plurality of laser input windows and for simultaneously directing the plurality of UV laser beams into the chamber respectively through the plurality of laser input windows wherein each of the plurality of directing lens is corresponded to at least one of the plurality of laser input windows.

8. The pulsed laser deposition system of claim 7, wherein each of the plurality of directing lenses comprises:
a reflecting lens for reflecting at least one of the UV laser beams and directing the UV laser beam into the corresponded laser input window wherein each of the laser input windows is corresponded to at least one reflecting lens; and
a focusing lens for focusing the UV laser beam which is split by the beam-splitting lens, reflected by the reflecting lens, and is desired to directed into the corresponded laser input window wherein each focusing lens is corresponded to one reflecting lens and one laser input window, and the focusing lens is deposed between the corresponded reflecting lens and the corresponded laser input window.

9. The pulsed laser deposition system of claim 7, wherein the beam-splitting device further comprises one or more density filter lenses for adjusting the intensity of the UV laser beams directed into the laser input windows wherein the density filter lenses are deposed between the beam-splitting lens and the reflecting lenses, between the reflecting lenses and the focusing lenses, or between the focusing lenses and the laser input windows.

10. The pulsed laser deposition system of claim 7, wherein the beam-splitting device further comprises one or more baffles for adjusting the intensity of the UV laser beams directed into the laser input windows wherein the baffles are deposed between the beam-splitting lens and the reflecting lenses, between the reflecting lenses and the focusing lenses, or between the focusing lenses and the laser input windows.

11. The pulsed laser deposition system of claim 7, wherein the beam-splitting device further comprises a second beam-splitting lens for splitting the split UV laser beams into more UV laser beams wherein the second beam-splitting lens is deposed between the beam-splitting lens and the reflecting lenses.

12. The pulsed laser deposition system of claim 1, wherein the UV laser source is a laser source capable of providing an excimer laser including various UV bands.

13. The pulsed laser deposition system of claim 1, wherein the target stage comprises:
a base;
a plurality of target holding stages deposed on the base for holding and carrying targets thereon;
a plurality of pillars deposed on the base wherein each of the target holding stages is deposed between two adjacent pillars and is pinjointed to the two adjacent pillars for being able to rotate between the two adjacent pillars; and
a target inclination controlling device for controlling inclination angles of the target holding stages to make the targets held on the target holding stages to be scanned back and forth by the UV laser beams with different inclination angles.

14. The pulsed laser deposition system of claim 13, wherein the target inclination controlling device comprises:
a plurality of inclination angle spindles wherein one end of each of the inclination angle spindles is hinge connected to one of the target holding stages for driving the target holding stage to rotate for being inclined with a predetermined angle; and
an inclination angle controlling column deposed on the base wherein the inclination angle controlling column is able to move up and down on the base and another end of each of the inclination angle spindles is hinge connected to the inclination angle controlling column so that each of the inclination angle spindles is able to move up and down following moving of the inclination angle controlling column for driving corresponded target holding stage to rotate upward or downward to control inclination angle of the corresponded target holding stage.

15. The pulsed laser deposition system of claim 14, wherein when the inclination angle controlling column moves up, the inclination angle controlling column drives the inclination angle spindles to move down for driving the target holding stages to rotate downward so that the target holding stages are inclined downward at a certain angle, and on the contrary, when the inclination angle controlling column moves down, the inclination angle controlling column drives the inclination angle spindles to move up for driving the target holding stages to rotate upward so that the target holding stages are inclined upward at a certain angle.

16. The pulsed laser deposition system of claim 13, wherein the pulsed laser deposition system further comprises a rotating device deposed under the target stage for rotating the target stage and thereby the target holding stages are able to be revolved or rotated back and forth around center of the target stage for changing the target holding stages respectively corresponded to the laser input windows to change targets of laser deposition and the targets put in the target holding stages are able to horizontally scanned back and forth by the UV laser beams.

17. The pulsed laser deposition system of claim 16, wherein the carrier stage comprises a cavity or carrier capable of putting or holding a substrate having a size of 6 inches to 12 inches thereon.

18. The pulsed laser deposition system of claim 17, wherein there is one or more small substrate containing pits deposed in the cavity or carrier for putting or holding one or more substrate having small size thereon to perform laser deposition.

19. The pulsed laser deposition system of claim 1, wherein the carrier stage further comprises a rotation-and-rise controlling device for controlling the carrier stage to rotate in order to perform laser deposition to all of the substrates put on the carrier stage uniformly and for rising and descending the carrier stage to control work distance between the carrier stage and the target stage.

20. The pulsed laser deposition system of claim 19, wherein the work distance is 10 centimeter (cm) to 40 centimeter (cm).

21. The pulsed laser deposition system of claim 1, further comprising a heating device deposed above or beside the carrier stage for heating the substrate put on the carrier stage to perform laser deposition.
